(19) United States
(12) Patent Application Publication
(10) Pub. No.: US 2012/0026681 A1
(43) Pub. Date: Feb. 2, 2012

(54) COLLAPSIBLE ELECTRONIC DEVICE AND ADJUSTMENT METHOD THEREOF

(75) Inventors: TING-KAI WANG, Tu-Cheng (TW); YIN-ZHI WU, Shenzhen City (CN); XIAO-GUANG CHENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/916,586

(22) Filed: Oct. 31, 2010

(30) Foreign Application Priority Data
Jul. 29, 2010 (CN) 201010240081.4

(51) Int. Cl. G06F 1/16; H05K 7/00

(52) U.S. Cl. 361/679.55; 361/679.01

(57) ABSTRACT

A collapsible electronic device includes a first part, a second part, a hinge, a control unit, and a driving unit. The second part is hinged on the first part, and the control unit is configured to generate a first driving command when receiving a power-on signal for the collapsible electronic device and a second driving command when receiving a power-down signal for the collapsible electronic device, and the driving unit is configured to pivot the hinge to a first predetermined angle when receiving the first driving command and to a second predetermined angle when receiving the second driving command.

### BACKGROUND

1. Technical Field

The present disclosure relates to electronic devices and, more particularly, to a collapsible electronic device and a method for adjusting orientation thereof.

2. Description of Related Art

A conventional collapsible electronic device, for example a notebook, includes a main body and a display hinged thereon, which can be pivoted to and stay in a desired position. The display must be manually pivoted to a desired position, however, which may not be convenient.

It is thus desirable to provide a collapsible electronic device and a method thereof to address the limitations described.

### BRIEF DESCRIPTION OF THE DRAWINGS

The components in the drawings are not necessarily drawn to scale, the emphasis instead being placed when clearly illustrating the principles of a collapsible electronic device and a method thereof. Moreover, in the drawings, like reference numerals designate corresponding parts throughout the several views.

FIG. 1 is a schematic view of a collapsible electronic device in accordance with an exemplary embodiment.

FIG. 2 is a block diagram of the collapsible electronic device of FIG. 1.

FIG. 3 is a flowchart of a method for adjusting orientation of a cover of a collapsible electronic device such as, for example, that of FIG. 1, in accordance with an exemplary embodiment.

### DETAILED DESCRIPTION

The disclosure is illustrated by way of example and not by way of limitation. It should be noted that references to “an” or “one” embodiment in this disclosure are not necessarily to the same embodiment, and such references mean at least one.

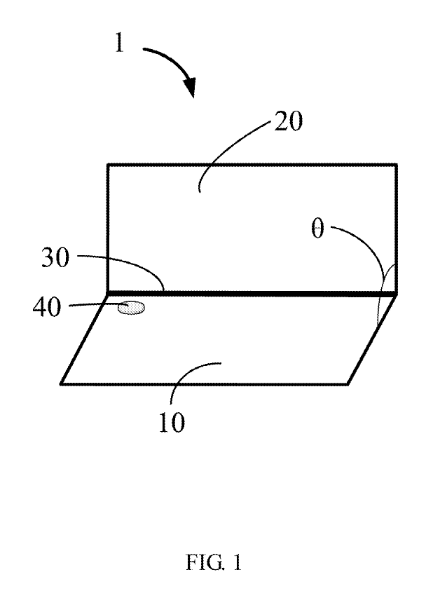

Referring to FIG. 1, a collapsible electronic device 1 includes a first part 10, a second part 20, a hinge 30, and a power button 40. The second part 20 is hinged on the first part 10 by the hinge 30, whereby the angle θ between the first part 10 and the second part 20 can be changed. The power button 40 is configured to generate a power-on signal to start the collapsible electronic device 1 and a power-down signal to shut the collapsible electronic device 1 down. The device 1 can also employ application keys to shut the collapsible electronic device 1 down. In the embodiment, the first part 10 is a main body housing electronic elements (not shown), and the second part 20 is a cover including a display screen, such as an LCD screen. The electronic device 1 may be a notebook computer, a mobile phone, or the like. In an alternative embodiment, at least one of the first part 10 and the second part 20 includes no electronic elements. For example, the second part 20 can merely be an upper cover.

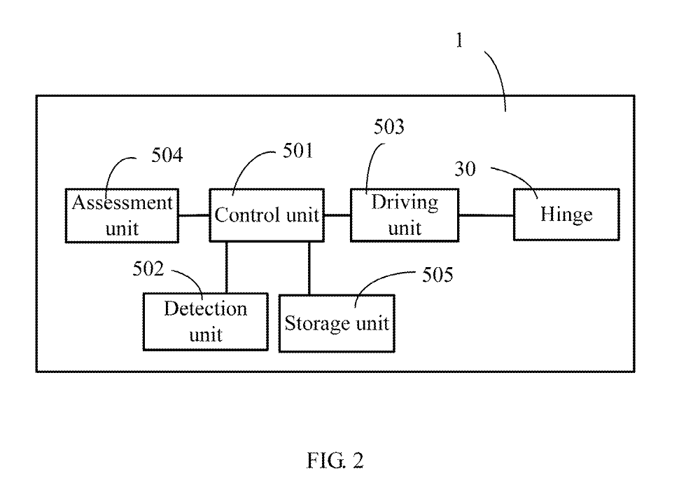

Referring to FIG. 2, the device 1 further includes a control unit 501 and a driving unit 503. The driving unit 503 is electrically connected to the control unit 501 and the hinge 30. The control unit 501 is configured to generate a first driving command when receiving the power-on signal, and generate a second driving command when receiving the power-down signal. The driving unit 503 is configured to pivot the hinge 30 to change the angle θ between the first part 10 and the second part 20 to a first predetermined angle θ1 when receiving the first driving command and a second predetermined angle θ2 when receiving the second driving command. In the embodiment, the driving unit 503 is a motor.

The device 1 further includes a storage unit 505 and a detection unit 502. The storage unit 505 stores a record of the first predetermined angle θ1 and the second predetermined angle θ2. The first predetermined angle θ1 is an angle between the first part 10 and the second part 20 when the device 1 is in an operating state, and the second predetermined angle θ2 is another angle between the first part 10 and the second 20 when the device 1 is in an idle state such as a power-down state or a standby state. In the embodiment, the first angle θ1 may be 105°, and the second angle θ2 may be 5° or 0°. The control unit 501 is further configured to generate a detection command when receiving the power-on signal or the power-down signal, and the detection unit 502 is configured to determine the angle θ between the first part 10 and the second part 20 when receiving the detection command.

The control unit 501 compares the detected angle θ with the first predetermined angle θ1 to obtain a first difference when receiving the power-on signal and generate the first driving command according to the first difference, and compares the detected angle θ with the second predetermined angle θ2 to obtain a second difference when receiving the power-down signal and generate the second driving command according to the second difference.

In the embodiment, the device 1 further includes an assessment unit 504 to generate an assessing signal in response to user input. The control unit 501 is further configured to inform the detection unit 502 to determine the current angle θ when receiving the assessing signal, compare the current angle θ with a third predetermined angle θ3 stored in the storage unit 505 to generate a third driving command, and direct the driving unit 503 to rotate the hinge 30 to the first predetermined angle θ1 if the detected angle θ is less than the third predetermined angle θ3 and to the second predetermined angle θ2 if the detected angle θ exceeds the third predetermined angle θ3 according to the third driving command.

In this embodiment, if detected angle θ is less than the third predetermined angle θ3, the device 1 is in the idle state, and exceeds the third angle θ3, the device 1 is in the operational state. The third angle θ3 may be 45°. In an alternative embodiment, the control unit 501 informs the detection unit 502 to determine the current angle θ when the duration of receiving the assessing signal reaches a predetermined time interval to prevent accidental activation.

In the embodiment, the assessment unit 504 may be a mechanical button or a touch button. In an alternative embodiment, the assessment unit 504 may be an infrared sensor.

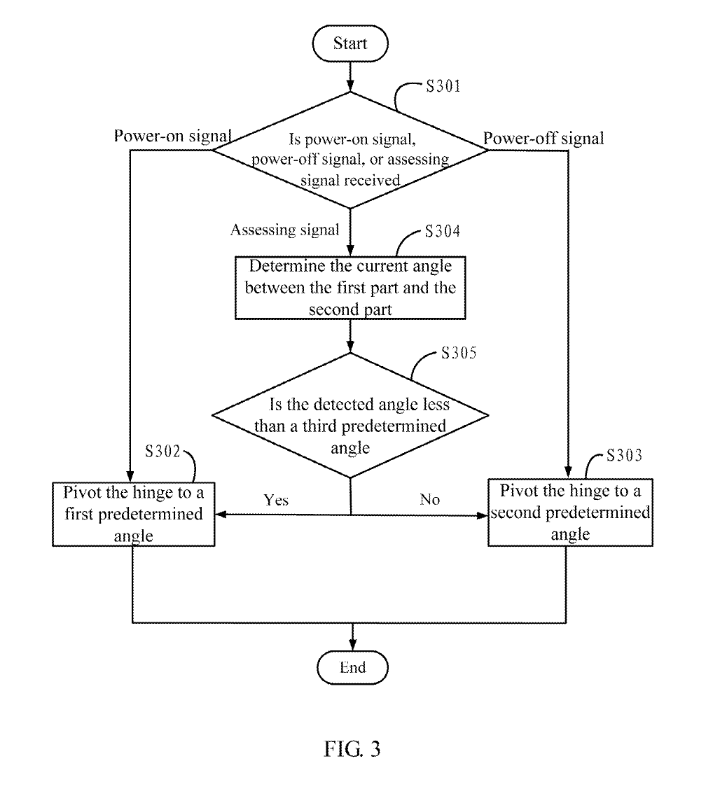

Referring to FIG. 3, a flowchart of a method for adjusting orientation of a cover of a collapsible electronic device is illustrated.

In step S301, the control unit 501 determines whether the power-on signal, the power-down signal, or the assessing signal is received. If the power-on signal is received, step S302 is implemented. If the power-down signal is received, step S303 is implemented. If the assessing signal is received, step S304 is implemented.

In step 302, the control unit 501 directs the driving unit 503 to rotate the hinge 30 to the first predetermined angle θ1. In detail, the control unit 501 directs the detection unit 502 to determine the angle θ between the first part 10 and the second part 20, compares the detected angle θ with the first predetermined angle θ1 to generate the first driving command, and directs the driving unit 503 to change the angle θ between the first part 10 and the second part 20 to the first predetermined angle θ1 according to the first driving command.

In step S303, the control unit 501 directs the driving unit 503 to rotate the hinge 30 to the second predetermined angle θ2. In detail, the control unit 501 directs the detection unit 502 to determine the angle θ between the first part 10 and the second part 20, compares the detected angle θ with the second predetermined angle θ2 to generate the second driving command, and directs the driving unit 503 to change the angle θ between the first part 10 and the second part 20 to the second predetermined angle θ2 according to the second driving command.

In step S304, the control unit 501 directs the detection unit 502 to determine the current angle θ between the first part 10 and the second part 20.

In step S305, the control unit 501 compares the detected angle θ with the third predetermined angle θ3. If the detected angle θ is less than the third predetermined angle θ3, step S302 is implemented, and if the detected angle θ exceeds the third predetermined angle θ3, step S303 is implemented.

Although the current disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A collapsible electronic device comprising:
a first part;
a hinge;
a second part hinged on the first part by the hinge;
a control unit configured to generate a first driving command when receiving a power-on signal for powering on the collapsible electronic device and generate a second driving command when receiving a power-down signal for powering off the collapsible electronic device; and
a driving unit configured to rotate the hinge to change the angle between the first part and the second part to a first predetermined angle when receiving the first driving command and a second predetermined angle when receiving the second driving command.

2. The collapsible electronic device as described in claim 1, further comprising a storage unit and a detection unit, wherein the storage unit stores a record of the first predetermined angle, the control unit is further configured to generate a detection command when receiving the power-on signal, the detection unit is configured to determine the angle between the first part and the second part when receiving the detection command, the control unit is further configured to compare the detected angle with the first predetermined angle to obtain a first difference and generate the first driving command according to the first difference, and the driving unit is configured to pivot the hinge to cause the angle between the first part and the second part to be the first predetermined angle according to the first driving command.

3. The collapsible electronic device as described in claim 2, wherein the storage unit further stores a record of the second predetermined angle, the control unit is further configured to generate the detection command when receiving the power-down signal, compare the detected angle with the second predetermined angle to obtain a second difference and generate the second driving command according to the second difference, and the driving unit is configured to pivot the hinge to cause the angle between the first part and the second part to be the second predetermined angle according to the second driving command.

4. The collapsible electronic device according to claim 3, further comprising a assessment unit, wherein the storage unit further stores a record of a third predetermined angle, the assessment unit is configured to generate an assessing signal in response to user inputs, the control unit is further configured to generate the detection command when receiving the assessing signal, compare the detected angle with the third predetermined angle to generate a third driving command, the driving unit is further configured to pivot the hinge to change the current angle between the first part and the second part to the first predetermined angle if the detected angle is less than the third predetermined angle and the second predetermined angle if the current angle exceeds the third predetermined angle according to the third driving command.

5. The collapsible electronic device according to claim 4, wherein the assessment unit is a mechanical button, a touch button, or an infrared sensor.

6. The collapsible electronic device according to claim 1, wherein the first part is a main body housing electronic elements, and the second part is a cover comprising a display screen.

7. The collapsible electronic device according to claim 6, wherein the display screen is an LCD screen.

8. The collapsible electronic device according to claim 6, wherein the second part is a cover with no electronic elements.

9. The collapsible electronic device according to claim 1, wherein the device is a notebook computer or a mobile phone.

10. A method for adjusting orientation of a collapsible electronic device, the collapsible electronic device comprising a hinge, a first part, and a second part hinged on the first part through the hinge, the method comprising:
determining whether a power-on signal for powering on the collapsible electronic device or a power-down signal for powering off the collapsible electronic device is received;
pivoting the hinge to change the angle between the first part and the second part to a first predetermined angle if the power-on signal is received;
pivoting the hinge to change the angle between the first part and the second part to a second predetermined angle if the power-down signal is received;

11. The method according to claim 10, wherein the step of pivoting the hinge to change the angle between the first part and the second part to a first predetermined angle if the power-on signal is received comprising:
detecting the angle between the first part and the second part if the power-on signal is received;
comparing the detected angle with the first predetermined angle to generate a first driving command; and
pivoting the angle between the first part and the second part to the first predetermined angle according to the first driving command.

12. The method according to claim 10, wherein the step of pivoting the hinge to change the angle between the first part and the second part to a second predetermined angle if the power-down signal is received comprising:
detecting the angle between the first part and the second part if the power-down signal is received;
comparing the detected angle with the second predetermined angle to generate a second driving command; and
pivoting the angle between the first part and the second part to the second predetermined angle according to the second driving command.

13. The method according to claim 10, wherein the collapsible electronic device further comprising an assessment unit configured to generate a assessing signal in response to user input, the method further comprising:
determining whether a assessing signal is received;
detecting the current angle between the first part and the second part;
determine whether the detected angle exceeds the third predetermined angle;
pivoting the hinge to change the angle between the first part and the second part to the first predetermined angle if the detected angle is less than the third predetermined angle; and
pivoting the hinge to change the angle between the first part and the second part to the second predetermined angle if the detected angle exceeds the third predetermined angle.
